(19) United States
(12) Patent Application Publication
(10) Pub. No.: US 2005/0088827 A1
(43) Pub. Date: Apr. 28, 2005

(54) Electrical card having heatsink device

(76) Inventor: Min Zhang, Dongguan City (CN)

Correspondence Address: MOLEX INCORPORATED, 2222 WELLINGTON COURT, LISLE, IL, 60532, US

(21) Appl. No.: 10/960,335

(22) Filed: Oct. 7, 2004

(30) Foreign Application Priority Data
Oct. 7, 2003 (TW) 92217943

(51) Int. Cl. H05K 7/20

(52) U.S. Cl. 361/720; 361/709

(57) ABSTRACT

The present invention is related to an electrical card having a heatsink device, in which the electrical card includes an upper cover, a lower cover, a printed circuit board, and a heatsink device. The upper cover assembles with the lower cover so as to form a housing with a cavity therein. The printed circuit board is inserted into the cavity of the housing. The printed circuit board includes at least one heat generating element. The heatsink device has at least one heat sink apparatus mounted on the heat generating element for dissipating heat thereof in order to make the heat generating element operate in its preferred operating temperature range.

### FIELD OF THE INVENTION

The present invention relates to an electrical card, and particularly to an electrical card that can be introduced into an electrical card connector for transmitting pre-stored data to those electronic appliances. The electrical card has a heatsink device for dissipating heat of the heat generating elements within the electrical card in order to allow the electrical card to operate in the appropriate operating temperature.

### BACKGROUND OF THE INVENTION

Electrical cards, such as PCMCIA Cards, can be inserted into or ejected from electrical card connectors of electronic appliances. After being electrically connected, the data pre-stored in the electrical cards can be transmitted to those electronic appliances, such as notebook computers, or the like.

A conventional electrical card mainly includes an upper cover, a lower cover, and a printed circuit board disposed between the upper cover and the lower cover. Microprocessor chips or other heat generating elements are mounted on the printed circuit board.

Conventional microprocessor chips in the electrical cards generally have lower performance requirements, thus there are no problems of heat dissipation. Newer generation microprocessor chips have a higher performance, and they produce a significant amount of heat. Thus, electrical cards using higher performance microprocessor chips without a heatsink device will not be able to operate within its recommended temperature range.

It is desirable to provide an improved electrical card with a heatsink device that overcomes the above problem.

### SUMMARY OF THE INVENTION

An object of the present invention is to provide an electrical card with a heatsink device, of which providing a heatsink device without increasing the height and the volume of the electrical card so as to dissipate heat for making the heat generating element of the electrical card run in an appropriate operating temperature.

In order to achieve the object set forth, an electrical card in accordance with the present invention includes an upper cover; a lower cover, assembling with the upper cover to form an housing having a cavity therein; a printed circuit board inserted into the cavity of the housing, the printed circuit board comprises at least one heat generating element; and a heatsink device having at least a heatsink apparatus mounted on the heat generating element.

Other objects, advantages, and novel features of the present invention will became more apparent from the following detailed description when taken in conjunction with the accompanying drawings.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is an exploded view of an electrical card according to the present invention, in which a heatsink device is introduced.

FIG. 2 is a perspective, assembled view of the electrical card of FIG. 1.

FIG. 3 is an isometric view of the electrical card of FIG. 1, viewed in a plan aspect.

### DETAILED DESCRIPTION OF THE DISCLOSED EMBODIMENTS

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

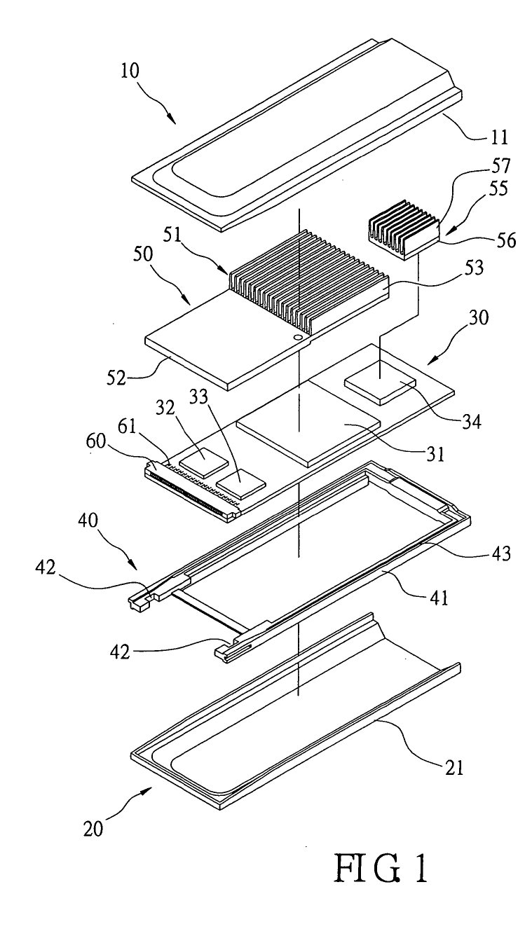

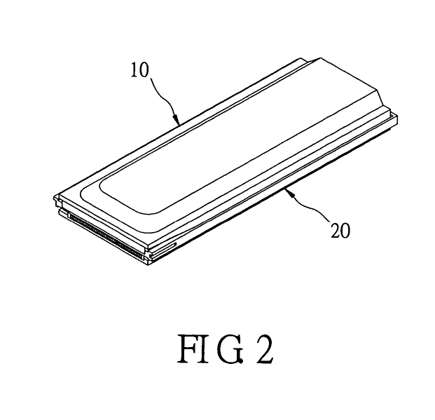

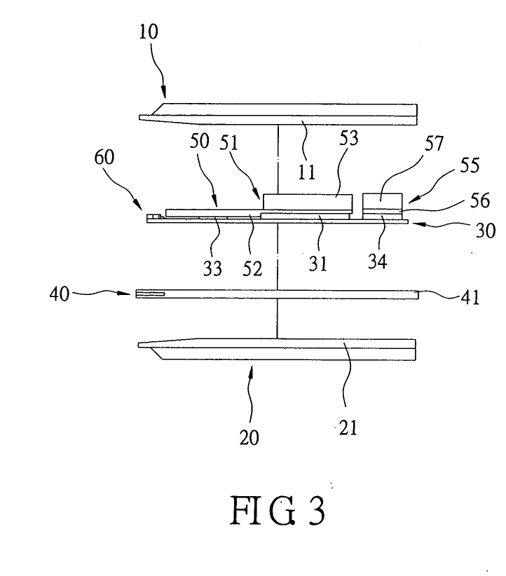

Referring to FIGS. 1-3, an electrical card having a heatsink device in accordance with the present invention comprises an upper cover 10, a lower cover 20, a printed circuit board 30, a plastic frame 40 and a heatsink device 50. The upper and lower covers 10 and 20 are made through pressing metal plates, and both of them have opposite sidewalls 11 and 21, respectively.

The printed circuit board 30 is inserted between the upper cover 10 and the lower cover 20, and a connector 60 is disposed at a front portion of the printed circuit board 30. The connector 60 has a plurality of conductive terminals 61 therein. A back end of each of the conductive terminals 61 extends outside the connector 60 for soldering and electrically connecting to the printed circuit board 30. A plurality of heat generating elements 31, 32, 33, 34, such as microprocessor chips are mounted on the printed circuit board 30.

The plastic frame 40 is disposed between the upper cover 10 and the lower cover 20. The plastic frame 40 has brackets 41 at both sides of opposite surfaces, respectively. Each of the brackets 41 includes a slot 42 formed at a front portion adjacent to a front end for fastening with the connector 60. Grooves 43 are disposed in an upper surface and a lower surface of each of the brackets 41 respectively for engaging with the sidewalls 11, 12 of the upper cover 10 and the lower cover 20. After assembled, curing sealants of the covers 11 and 12 to form a housing having a cavity therein for receiving the printed circuit board 30 in the cavity. Also, the housing can be achieved from jointing the covers 11 and 12 in other states.

The heatsink device 50 has at least a heatsink apparatus mounted on the heat generating elements. In this embodiment, the heatsink device 50 has a first heatsink apparatus 51 mounted on heat generating elements 31, 32, 33, and a second heatsink apparatus 55 mounted on heat generating element 34.

The first heatsink apparatus 51 includes a base plate 52 and a plurality of heatsink plates or fins 53. The first heatsink apparatus 51 can be made from molding or assembling process. The heatsink plates 53 and the base plate 52 are made form conductive metal material, and the heatsink plates 53 are parallel and alternately disposed on a top surface of the base plate 52 so as to form paths for airflow therebetween. The first heatsink apparatus 51 is mounted on heat generating elements 31, 32, 33, and a bottom surface of the base plate 52 contacts with an outer surface of the heat generating elements 31, 32, 33. The bottom surface of the base plate 52 can form as a step shaped according to the height of the heating surface of the electric heating elements 31, 32, and 33 so as to contour the contact with the outer surfaces of the heat generating elements to improve heat dissipation efficiency. Sealant and/or thermal paste (not shown) can be introduced between the base plate 52 and the electric heating elements 31, 32, and 33 to further improve the heat dissipation.

Furthermore, the first heatsink apparatus 51 also can be mounted on the outer surfaces of the heat generating elements 31, 32, 33 by using a latching mechanism, in which heat dissipated by the heat generating elements 31, 32, 33 can be conducted to the first heatsink apparatus 51.

The second heat sink apparatus 55 includes a base plate 56 and a plurality of heatsink plates or fins 57. The first heatsink apparatus 55 can be made from molding or assembling process. The heatsink plates 57 and the base plate 56 are made form conductive metal material, and the heatsink plates 57 are parallel and alternately disposed on a top surface of the base plate 56 so as to form floating paths for airflow therebetween. The second heatsink apparatus 55 is mounted on the heat generating elements 34, and a bottom surface of the base plate 56 contacts with an outer surface of the heat generating elements 34. Sealant and/or thermal plates (not shown) can be introduced between the base plate 56 and the heat generating element 34 to further improve the heat dissipation. Moreover, the second heatsink apparatus 55 also can be mounted on the outer surface of the heat generating element 34 by using a latching mechanism, in which heat dissipated by the heat generating element 34 can be conducted to the second heatsink apparatus 55.

The electrical card in accordance with the present invention has heatsink apparatus 51 and 55 arranged in a housing thereof. And the heatsink apparatus 51 and 55 are mounted on the printed circuit board 30, and in the original cavity between the upper and lower cover 10 and 20. Thereby the electrical card has a constant size without increasing the height and the volume thereof.

According to the foregoing description, the heatsink device 50 engaging between the upper and lower cover 10 and 20 for dissipating heat of the electric heating element thereof in order to make the electric heating element run in an appropriate operating temperature.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An electrical card, comprising:
an upper cover;
a lower cover, the lower cover assembled with the upper cover to form an housing having a cavity therein;
a printed circuit board inserted into the cavity of the housing, the printed circuit board comprising at least one heat generating element; and
a heatsink device having at least a heatsink apparatus mounted on the heat generating element.

2. The electrical card as claimed in claim 1, wherein the upper cover and the lower cover comprising opposite sidewalls respectively, a plastic frame is arranged between the upper cover and the lower cover, the plastic frame comprising brackets formed at each side thereof respectively, each of the brackets comprising grooves disposed in an upper surface and a low surface respectively so as to engage with the sidewalls of the upper cover and the lower cover.

3. The electrical card as claimed in claim 1, wherein the printed circuit board further comprising a connector disposed at a front portion thereof.

4. The electrical card as claimed in claim 1, wherein the heatsink apparatus comprises a base plate and a plurality of heatsink fins extending from the base plate in a direction away from the heat generating element.

5. The electrical card as claimed in claim 4, wherein a bottom surface of the baseplate is in contact with an outer surface of the heat generating element.

6. The electrical card as claimed in claim 1, wherein the heat sink device is mounted on a plurality of heat generating devices.

7. The electrical card as claimed in claim 1, wherein the heat sink device includes a plurality of heat sink apparatuses.

8. The electrical card as claimed in claim 1, wherein a thermal paste is placed between the heat generating element and the heat sink apparatus.

9. The electrical card as claimed in claim 5, wherein a thermal paste is placed between the heat generating element and the base plate.
